(19) United States
(12) Patent Application Publication
(10) Pub. No.: US 2010/0179977 A1
(43) Pub. Date: Jul. 15, 2010

(54) SAMPLED FILTER WITH FINITE IMPULSE RESPONSE

(75) Inventors: James Wei, Grenoble (FR); Dominique Morche, Meylan (FR)

Correspondence Address: LARIVIERE, GRUBMAN & PAYNE, LLP, 19 UPPER RAGSDALE DRIVE, SUITE 200, MONTEREY, CA, 93940, US

(73) Assignee: COMMISSARIAT A L'ENERGIE ATOMIQUE, PARIS (FR)

(21) Appl. No.: 12/523,393

(22) PCT Filed: Jan. 15, 2008
(86) PCT No.: PCT/EP2008/050382

§ 371 Date: Jan. 28, 2010

(30) Foreign Application Priority Data
Jan. 16, 2007 (FR) 07/00288

(51) Int. Cl. G06F 17/17; H03M 1/66

(52) U.S. Cl. 708/313; 341/144

(57) ABSTRACT

The invention relates to sampled filters with finite impulse response, or FIR filters.

According to the invention, there is proposed an FIR filter comprising a transconductance amplifier with controllable gain (AGM), at least one sampling capacitor (C_{E}) intended to receive an output current (di) from the amplifier and to periodically accumulate the charges produced by N successive samples of this current, and means for controlling the gain of the amplifier to give the amplifier a desired individual gain for each of the N samples. The weighting of the coefficients of the finite impulse response filter is effected through the transconductance gain of the amplifier and not through the value of a capacitor.

The invention relates to sampled filters with finite impulse response, or FIR filters.

Such a filter is a circuit which samples an analog signal in a particular manner: N successive samples are taken at a sampling frequency Fe, and the N samples are added together, weighted by individual coefficients which are chosen according to the filtering transfer function to be obtained. The output of the circuit consists of samples provided at a frequency Fe/N, that is to say the sampling frequency divided by the number of summed samples; this succession represents the analog signal sampled at the frequency termed the “decimation frequency” Fe/N and assigned a filtering function which is determined by the choice of the N weighting coefficients. The number N can be about ten or several tens, or indeed even several hundred.

Filtering of this type can be used for example to process a radiofrequency signal while simultaneously making a change of frequency to an intermediate frequency or a baseband, and a filtering for rejecting noise or neighboring telecommunications bands.

The sampled filtering comprises at least one sample-and-hold unit, simple or differential depending on whether the input signal is simple or differential. The sample-and-hold unit can receive the signal either in the form of voltage, or in the form of current. To work at high sampling frequency, it is often preferable to use a current. This makes it possible to reduce the influence of the clock noise; the clock noise (sometimes also called clock jitter) actually disturbs voltage-based sampling more than current-based sampling.

As the input signal to be converted generally takes the form of a voltage (or more exactly of high-frequency voltage variations), it is necessary to place upstream of the sampling capacitor or capacitors a high-quality transconductance amplifier which will convert the voltage variations very precisely into current variations.

FIR filters using a transconductance amplifier whose output is applied to sampling capacitors have already been proposed in the prior art. The most conventional structure comprises N sampling capacitors at the output of the transconductance amplifier. The conversion is done over N cycles and the current to be sampled is steered successively to the various capacitors by switches. Then, at the end of the N cycles, the stored charges corresponding to the N samples are summed, by means of an operational amplifier, on a common capacitor. The individual weighting of the samples is done by giving different values to the N capacitors. If the number N is large, many capacitors are required, and if the coefficients of the FIR filter must be programmable so as to modify the filtering function, each capacitor must have a programmable value. The programming of a coefficient is then done by selecting one from among several possible capacitors, and it is understood that this further multiplies the number of capacitors and the number of switches for steering to each of the possible capacitors. There are problems of bulkiness, problems of pairing of the capacitors, and problems of glitches introduced by the very numerous switches necessary in the system.

Other structures of filters have been proposed: examples thereof will be found in the following documents:

S. Karvonen et al., “A 50-MHz CMOS Quadrature Charge Sampling Circuit with 66 dB SFDR”, Proceedings of the 2004 IEEE International Symposium on Circuits and Systems, Vancouver, pp 217-220, May 2004. The coefficients of the filter are not programmable.

U.S. Pat. No. 7,023,245, “Versatile charge sampling circuits”, Apr. 4, 2006. The sampled signal is a voltage and not a current and this voltage is applied to a capacitor through a resistor of programmable value. The input signal is attenuated in a variable manner; the attenuation is dependent on the time constant of the arrangement, itself variable since the resistance varies. The passband is necessarily limited by this time constant. Finally, it is not possible to achieve any coefficient whatsoever with this arrangement, and in particular not coefficients greater than 1.

The aim of the invention is to propose a better architecture for achieving a sampled filter operating by charge integration.

According to the invention, there is proposed a sampled filter with finite impulse response which is characterized in that it comprises a transconductance amplifier with controllable gain, at least one sampling capacitor intended to receive an output current from the amplifier and to periodically accumulate the charges produced by N successive samples of this current, and means for controlling the gain of the amplifier to give the amplifier a desired individual gain for each of the N samples.

There may be two sampling capacitors linked to the output, working alternately on series of N successive samples, one of the capacitors operating by sampling while the other operates by holding and reading the accumulated charge, the roles being reversed during the following series.

The amplifier can operate differentially. The sampling is done simultaneously on the two outputs; thereafter, to obtain the differential sampling signal, the difference between the two samples originating from the two differential outputs is taken. The weighting coefficient is the same for the two samples.

And moreover, if the filter must perform a phase quadrature sampling I,Q providing, on its output or outputs, samples I and samples Q in phase quadrature, then the number of sampling capacitors is again doubled: there are as many sampling capacitors intended to accumulate N samples I as sampling capacitors intended to accumulate N samples Q.

Consequently, if the sampled filter works in alternation (hold phase alternated with a reading phase for one capacitor and reversal of these phases for the other), if moreover it operates differentially, and if finally it provides phase quadrature samples, it is understood that in principle eight different sampling capacitors are required.

To adjust the gain of the transconductance amplifier, it is possible to use notably
a network of resistors which can be controlled by logic signals to adjust the gain of the transconductance amplifier; the network forms for example a divider bridge with controllable ratio;
or else a MOS transistor to constitute a variable resistor controlled by a gate voltage, with a digital-analog converter for receiving gain control logic signals and converting them into an analog gate voltage of the transistor.

This network of resistors or this MOS transistor can be placed at the voltage input of the transconductance amplifier, so as to receive a voltage signal and attenuate this voltage in an adjustable ratio before converting the attenuated voltage into current with a transconductance gain defined by the core of the amplifier. They can also be placed inside the transconductance amplifier itself if the latter possesses a structure comprising a resistive element for transforming voltage variations into current variations with a gain determined by the value of the resistance of the element; it is then this resistive element which is constituted by a network of resistors selectable by logic signals or by a MOS transistor controlled by a variable gate voltage.

Other characteristics and advantages of the invention will become apparent on reading the detailed description which follows and which is given with reference to the appended drawings in which:

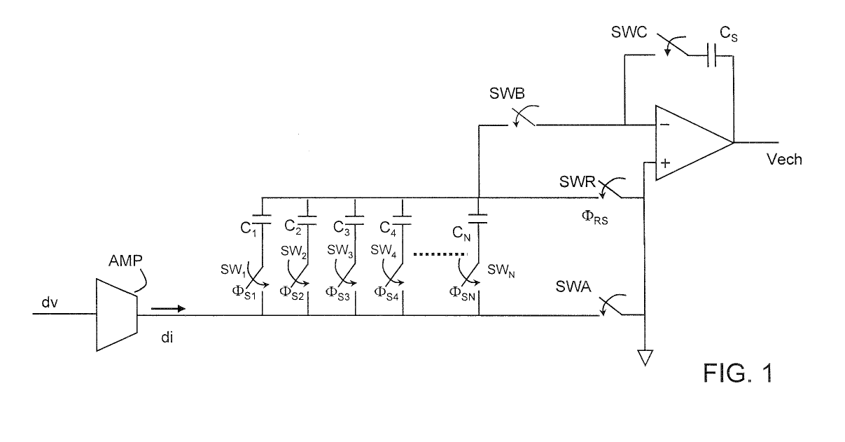

FIG. 1 represents an FIR filter of the prior art;

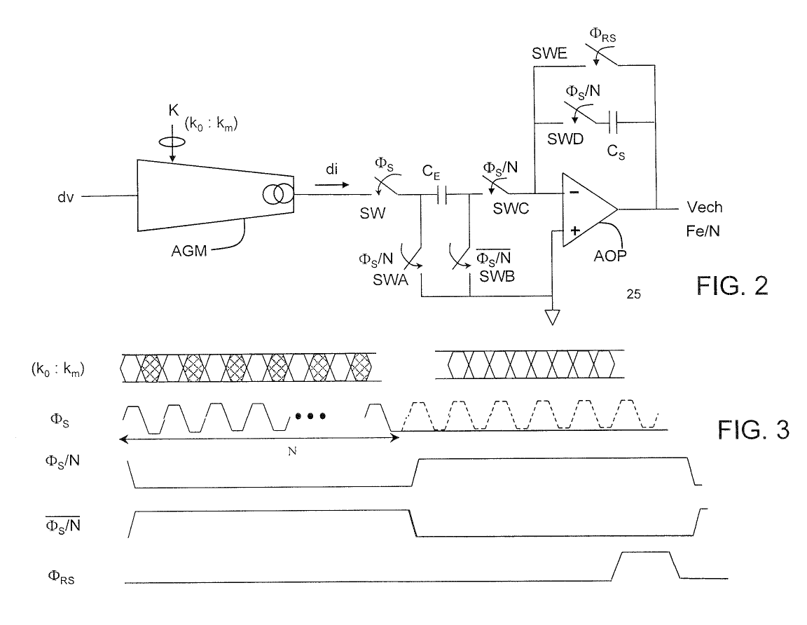

FIG. 2 represents the general principle of the invention;

FIG. 3 is an operating timechart of the circuit of FIG. 1;

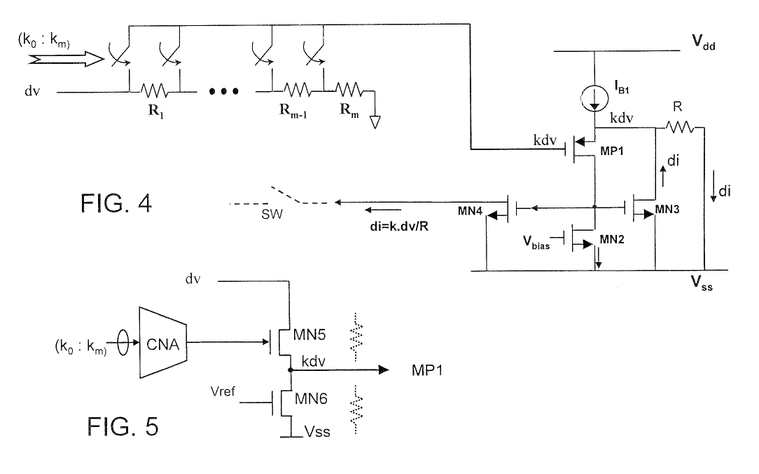

FIG. 4 represents an exemplary transconductance amplifier usable in the invention;

FIG. 5 represents another exemplary embodiment of the gain control in the transconductance amplifier;

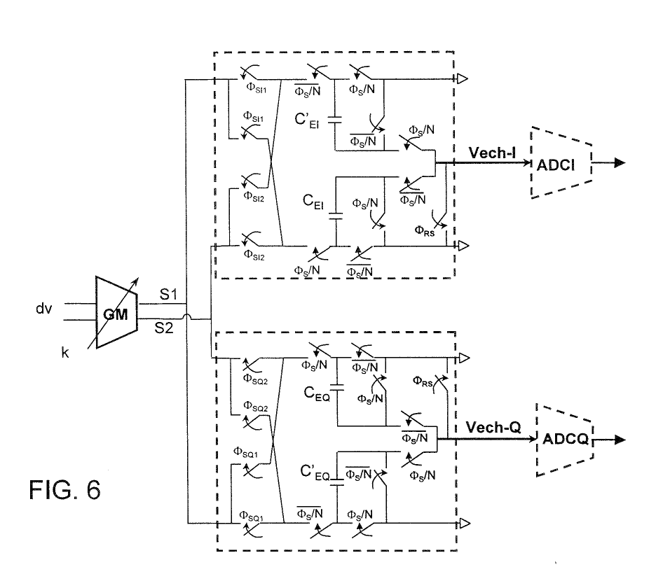

FIG. 6 represents an I,Q sampled filter according to the invention, using a variable-gain transconductance amplifier;

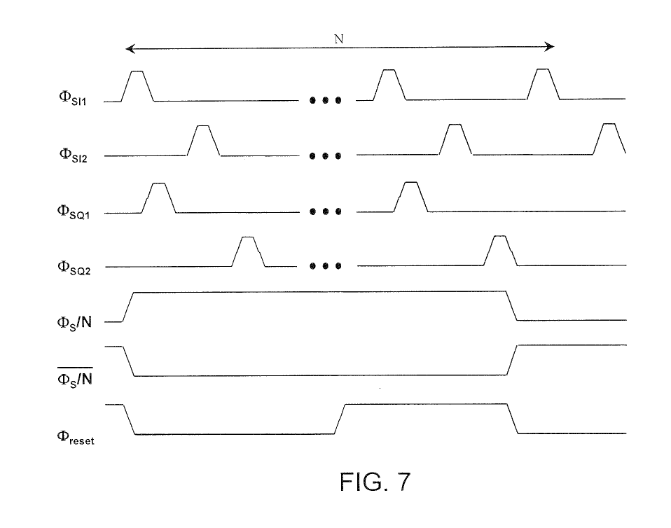

FIG. 7 represents the timechart corresponding to the actuation of the switches of FIG. 6.

The most traditional layout of a sampled filter with finite impulse response operating by sampling charges and not voltages is represented in FIG. 1.

A transconductance amplifier AMP converts the voltage input signal dv (only small signals are considered here, and not the common-mode biases or voltages) into a current di. The current is applied successively by breakers SW₁, SW₂, SW₃, . . . SW_{N}, under the control of a sampling sequencer (not represented), to N capacitors C₁, C₂, C₃ . . . C_{N}. During this time the other terminal of the capacitors is grounded by a closed switch SWR. At each sampling period a determined capacitor integrates the current di for a time which is the same for all the capacitors (half a clock period at frequency Fe for example); at the following period it is the following capacitor which integrates the charges. The successive sampling phases are designated by Φ_{S1}, Φ_{S2}, Φ_{S3}, . . . Φ_{SN}. The charge integrated in the capacitors takes values which represent the successive samples of the input voltage dv. After a cycle of N sampling phases Φ_{S1}, Φ_{S2}, Φ_{S3}, . . . Φ_{SN}, the capacitors are each charged by a respective sample of charges. The switch SWR is then opened and all the switches SW₁, SW₂, SW₃, . . . SW_{N} are reclosed. Three other switches which were open during the N sampling phases are also closed: a switch SWA which grounds all the switches SW₁, SW₂, SW₃, . . . SW_{N}, a switch SWB which links the capacitors to the negative input of an operational amplifier AOP, and a switch SWC which connects a summation capacitor Cs between this negative input and the output of the operational amplifier. The charges stored in the N capacitors C₁, C₂, C₃ . . . C_{N} are transferred to the capacitor C_{S} where they add together. The output voltage of the amplifier then represents a summation of N samples, and the weighting of the samples is determined by the individual values of the N capacitors, a sample of charges being the product of the current di times the value of the capacitor associated with this sample. The sample provided at the output is established with a decimation frequency Fe/N. All the capacitors are discharged towards the end of the closing phase of the switches SWA, SWB and SWC by a reclosing of the reset to zero switch SWR (phase of resetting to zero Φ_{RS} before the switches SWA, SWB and SWC, actuated at the frequency Fe/N, reopen for a new cycle of N sampling phases.

As has been stated, this type of sampler uses numerous capacitors, especially if each capacitor must have a programmable value as is the case for an FIR filter with programmable weighting coefficients. The number of switches is also very large. This poses problems of routing connections, of pairing the capacitors, and glitches due to the very numerous switchings.

FIG. 2 represents the principle of the sampled filter according to the invention, applied to an active integration of charges, that is to say by using an operational amplifier. The operational amplifier is however not compulsory.

There are no longer N sampling capacitors but just one, designated by C_{E}. There is still an operational amplifier AOP with a loopback capacitor C_{S}. Switches are provided, one of them (SW) being actuated at the sampling frequency Fe and the others (SWA, SWB, SWC, SWD) being actuated at the decimation frequency Fe/N, where N is here again the number of samples which will be summed with weighting so as to periodically provide, after each series of N integration cycles, a voltage sample Vech at the output of the operational amplifier AOP.

The filter comprises a controlled-gain transconductance amplifier AGM. The gain can be controlled by a gain control input designated by K. The gain can take an arbitrary value k from among m possible values k₀ to kₘ. The control is a digital control and it will be seen further on how it is possible to achieve this control. The gain considered here is a transconductance gain, namely the ratio di/dv between the current for small signals at the output of the amplifier and the voltage for small signals at the input.

The output of the transconductance amplifier is applied, through the switch SW, to a first terminal of the sampling capacitor C_{E}. This terminal can be grounded V_{SS} by the switch SWA, actuated at the frequency Fe/N. The closing phase for SWA is designated by Φ_{S}/N. The other terminal of the capacitor C_{E} can be grounded by the switch SWB actuated in phase opposition with SWA. Moreover it can be linked to the negative input of the operational amplifier AOP by the switch SWC actuated in phase with SWA. The positive input of the amplifier AOP is grounded. The output capacitor or loopback capacitor C_{S} has a terminal connected to the output of the amplifier AOP so as to establish the output sampling voltage Vech at the decimation frequency Fe/N. The other terminal of the capacitor can be linked to the negative input of the amplifier AOP by the switch SWD actuated in phase with SWA and SWC. Finally, a reset to zero switch SWE, actuated during a phase Φ_{RS}, slightly before the end of the closing phase Φ_{S}/N for the switches SWA and SWC, makes it possible to reset the charge of the capacitor Cs, and consequently the charge of the capacitor C_{E}, to zero.

The operating timechart of this circuit is recalled in FIG. 3.

The circuit operates in the following manner: for a given response curve of the filter, it is necessary to define the N weighting coefficients associated with the N samples of a cycle. There are not necessarily N values which are all different; there may be m possible values and the response of the filter is defined by the sequence of N values where each value is taken from among m possible values. To each possible value there corresponds a gain k taken from among the possible gain values k₀ to kₘ. Within each cycle of N samples, the transconductance amplifier is given a fast succession (at the frequency Fe) of different gains k taken from among the m values.

The transconductance amplifier AGM therefore produces a succession of current samples di which represent the input voltage sample dv weighted by a gain k which will be different from one sample to another: di=k·dv. Each current sample is integrated in the capacitor C_{E} for a fixed duration of closure of the switch SW; each sample of charges is therefore weighted, not by the value of the capacitor but by the value of the transconductance gain of the amplifier AGM.

In a cycle of N clock phases with frequency Fe, N weighted samples of charges are applied successively by the switch SW to the capacitor C_{E}, without resetting the latter to zero at each switching. The switches SWA, SWC, SWD are open. The switch SWB is closed. The weighting value k is modified at the tempo of the clock Fe, this taking place while the switch SW is open.

After N sampling phases, the capacitor C_{E} has gathered the sum of N charge samples weighted by the gains k.

A phase of reading the charge accumulated in the capacitor C_{E} is then entered: the switch SWB is opened and the switches SWA, SWC, SWD are closed. The switch SWE is open.

The switch SW is preferably held open during the reading phase. However, it is also possible to provide another switch, not represented, between the switch SW and the capacitor C_{E}, to completely disconnect the capacitor C_{E} from the transconductance amplifier throughout the reading phase even if the switch SW continues to open and close at the frequency Fe. This additional switch is anyway necessary in the systems with alternate sampling where a sample is captured in a capacitor C_{E} during the reading of a capacitor C′_{E} and vice versa. It is controlled by the complement of the signal Φ_{S/N} and it steers the samples of current to the other capacitor C′_{E} during the reading of C_{E} and vice versa.

The loopback capacitor C_{S} gathers the weighted sum of charges accumulated in the capacitor C_{E}. The output voltage Vech represents an output sample of the sampled filter. This sample is renewed at the decimation frequency Fe/N.

The sample Vech can be utilized downstream during the first part of the phase Φ_{S}/N where the switches SWA, SWC, SWD are closed and SWE is open. Before the end of this phase, the switch SWE is closed (phase Φ_{RS}) for resetting to zero of the capacitors C_{S} and C_{E}.

FIG. 4 represents an exemplary adjustable-gain transconductance amplifier that may be used to make the finite impulse response filter according to the invention. The input voltage for small signals dv is applied to a divider bridge with m resistors R₁ to Rₘ. The output of the divider bridge provides a voltage kdv which varies according to the position of the output node of the divider bridge. A switch associated with each node makes it possible to select a division ratio value k, under the control of digital signals. The digital signals are applied at the sampling frequency so that to each sample with frequency Fe there corresponds a division ratio value k. The values of the resistors are all identical or else they are different from one another: this depends on the values of the m desired weighting coefficients.

It would also be possible to have a smaller number of resistors than the number of coefficients to be achieved, if there is the possibility of closing several switches at one and the same time to establish certain division ratios.

The output voltage of the divider bridge, kdv, is applied to the gate of a PMOS transistor MP1 arranged in follower mode, which transfers this voltage kdv to its source. The transistor is supplied by a current source I_{B1} and it is in series with an NMOS transistor MN2 arranged in constant current source mode, whose gate is biased by a constant voltage V_{bias}. A resistor of value R is linked between the source of MP1 and ground and is traversed by a current di=k·dv/R. A transistor MN3 is disposed between the source of MP1 and ground; its gate is controlled by the linked drains of MP1 and MN2.

Schematically, for simplicity it may be said that the current k·dv/R in the resistor R cannot originate from the current source I_{B1} or from the current in the transistor MP1 since these currents are constant and do not vary with dv. Consequently it can only originate from the transistor MN3. The transistor MN3 is therefore traversed by a current di=kdv/R.

An output transistor MN4, identical to the transistor MN3, is arranged in current mirror mode and provides on its drain a current di=k·dv/R; it is this current weighted by the division ratio k which is applied to the breaker SW of FIG. 2.

Rather than a divider bridge with multiple resistors R₁ to Rₘ, it would be possible to use a variable resistor controlled by an analog signal. Typically this variable resistor would then consist of a MOS transistor MN5 whose gate is controlled by a variable analog voltage, and this analog voltage can be provided by a digital-analog converter (DAC) which receives in digital torm, at the sampling frequency Fe, a weighting coefficient value to be established. FIG. 5 represents such an arrangement which can be substituted for the divider bridge of FIG. 4: the bridge now comprises only the transistor MN5 and a resistor, and the resistor can itself be embodied in the form of a MOS transistor MN6 whose gate is at a fixed potential.

Whether there is a bridge with two resistors (FIG. 5) or a bridge with m resistors (FIG. 4), it is understood that even if the number m of possible values of coefficients is limited, the number N of samples is not limited, and it is possible to formulate sophisticated filtering functions.

Finally, rather than producing a divider bridge at the input of the transconductance amplifier, upstream of the transistor MP1, it is possible to envisage using a variable resistor or a controllable network of resistors in place of the resistor R which determines the voltage/current conversion ratio. Indeed, if the voltage dv is applied directly to the gate of the transistor MP1, and if there is a resistance R/k instead of R, it is understood that the current produced is again di=kdv/R.

The transconductance amplifier represented in FIG. 4 is not differential. A differential amplifier could be produced with two symmetric amplifiers, the resistance R which was linked to ground then being replaced with a resistance 2R linked between the sources of the transistors MP1 of the two amplifiers.

FIG. 6 represents a finite impulse response filter according to the invention, applied to the case where the input signal is differential and serves to establish samples I and samples Q in phase quadrature, the filter using for each sample two filtering capacitors operating in sampling/reading alternation. The output of this filter is not differential; however the variable-gain transconductance amplifier AGM is differential and comprises two outputs S1 and S2. If the output of the filter had to be differential, it would be necessary to double the number of capacitors and provide associated switches.

There are two sampling capacitors C_{EI} and C′_{EI} working in alternation to accumulate the samples I, and two sampling capacitors C_{EQ} and C′_{EQ} working in alternation to accumulate the samples Q. Furthermore, each capacitor successively receives a sample of charges from the differential output S1 followed by a sample of charges from the differential output S2, with opposite signs, in such a manner that the samples add together and do not subtract in the capacitor. Provision is therefore made that the outputs S1 and S2 provide the charges with the same sign.

The capacitors C_{EI} and C_{EQ} receive samples during the phases Φ_{S}/N of the decimation frequency Fe/N. They are read during the complementary phases of this frequency. The resetting to zero by the phase Φ_{RS} takes place at the end of the complementary phase. The capacitors designated by the prime index work in alternation with the first capacitors.

In FIG. 6, the switches of the filter are designated by the phases which control them; these switches are of three sorts:
those which are actuated by pulses at the sampling frequency Fe and which play the role of the switch SW of FIG. 2; the index 1 in the name of the phase signifies that they apply to a capacitor the output S1 of the differential transconductance amplifier; the index I or Q signifies that they relate to the storage of a sample I or Q;
those which are actuated by the decimation frequency Fe/N and which play the role of the switches SWA or SWC of FIG. 2 during a sampling phase and SWB during the reading phase, both for the capacitors C_{E} and for the capacitors C′_{E}, the phases being reversed for the latter;
and those which are actuated by the reset to zero pulse Φ_{RS} and which play the role of the switch SWE of FIG. 2.

During a sampling phase relating to the capacitors C_{EI} and C_{EQ} four switchings occur successively:
application of a sample of charges from the output S to the capacitor C_{EI};
in phase quadrature, that is to say with a temporal shift of a quarter of a period 1/Fe of the sampling clock, application of a sample of the output S1 to the capacitor C_{EQ};
at the following clock tick, application of a sample of the output S2 to the capacitor C_{EI};
and finally, with a new quadrature shift, application of a sample of the output S2 to the capacitor C_{EQ}.

The timechart of the corresponding signals is represented in FIG. 7.

The output of the sampling block for the I pathway provides a sampled analog level Vech-I; the output of the sampling block for the Q pathway provides a sampled analog level Vech-Q.

A sampling using an operational amplifier AOP has not been represented in FIG. 6. Such an amplifier is optional anyway. Represented downstream of the FIR filter is an analog-digital converter ADCI and ADCQ on the respective I and Q pathways, for an application where digital outputs are desired.

The sampled filter according to the invention can be used for example to carry out a low-pass or bandpass filtering function at the same time as a frequency change function. It is possible to filter the noise and the jamming signals in radio receiver applications. Adaptation of the passband and of the frequency response are possible by exploiting the programmable aspect of the weighting coefficients of the samples and by exploiting the number N of samples.

With a layout such as that of FIG. 6, the switches linked to the differential outputs S1 and S2 make it possible to reverse the polarity of the output signal. It is therefore possible to generate a positive weighting coefficient or a negative weighting coefficient, according to the position of the switches.

1. A sampled filter with finite impulse response, characterized in that it comprises a transconductance amplifier with controllable gain (AGM), at least one sampling capacitor (C_{E}) intended to receive an output current (di) from the amplifier and to periodically accumulate the charges produced by N successive samples of this current, and means for controlling the gain of the amplifier to give the amplifier a desired individual gain for each of the N samples.

2. The sampled filter as claimed in claim 1, characterized in that it comprises at least two sampling capacitors (C_{EI}, C′_{EI}) linked to the output of the amplifier, working alternately on series of N successive samples, one of the capacitors operating by sampling while the other operates by holding and reading the accumulated charge.

3. The sampled filter as claimed in one of claims 1 and 2, characterized in that the transconductance amplifier comprises two differential outputs (S1, S2) both applied to at least one same sampling capacitor (C_{EI}).

4. The sampled filter as claimed in one of claims 1 to 3, for a phase quadrature sampling providing, on its output or outputs, samples I and samples Q in phase quadrature with one another, characterized in that it comprises as many sampling capacitors (C_{EI}, C′_{EI}) intended to accumulate N samples I as sampling capacitors (C_{EQ}, C′_{EQ}) intended to accumulate N samples Q.

5. The sampled filter as claimed in one of claims 1 to 4, characterized in that it comprises a network of resistors (R₁, . . . Rₘ) which can be controlled by logic signals to adjust the gain of the transconductance amplifier.

6. The sampled filter as claimed in one of claims 1 to 5, characterized in that it comprises a MOS transistor (MN5) to constitute a variable resistor controlled by a gate voltage, and a digital-analog converter (DAC) for receiving gain control login signals and converting them into a gate voltage of the transistor.

7. The sampled filter as claimed in one of claims 5 and 6, characterized in that the means for adjusting the gain is placed at the voltage input of the transconductance amplifier, so as to receive a voltage signal and attenuate this voltage in an adjustable ratio before converting the attenuated voltage into current.

8. The sampled filter as claimed in one of claims 5 and 6, characterized in that the transconductance amplifier comprises a resistive element (R) for transforming voltage variations (dv) into current variations (di) with a gain determined by the value of the resistor, and in that this resistive element is a set of resistors selectable by logic signals so as to constitute a resistor having a value chosen from among several possible values.

9. The sampled filter as claimed in one of claims 5 and 6, characterized in that the transconductance amplifier comprises a resistive element (R) for transforming voltage variations (dv) into current variations (di) with a gain determined by the value of the resistor, and in that this resistive element is a MOS transistor controlled by a variable gate voltage.
